(19) United States
(12) Patent Application Publication
(10) Pub. No.: US 2026/0293030 A1
(43) Pub. Date: Sep. 24, 2026

(54) LOW-INDUCTANCE DC LINK HAVING GEL FRAME

(71) Applicant: Robert Bosch GmbH, Stuttgart (DE)

(72) Inventors: Christian Breuning, Nuertingen (DE); Christoph Burkhardt, Tuebingen (DE); Wolfram Kienle, Magstadt (DE)

(21) Appl. No.: 19/489,322

(22) PCT Filed: May 17, 2024
(86) PCT No.: PCT/EP2024/063721

§ 371 Date: Feb. 25, 2026

(30) Foreign Application Priority Data
Jun. 2, 2023 (DE) 10 2023 205 191.5

(51) Int. Cl. H05K 7/14

(52) U.S. Cl. CPC H05K 7/14329

(57) ABSTRACT

The present invention describes a low-inductive DC circuit (1) between a circuit breaker (2) and a passive electrical component (3). The low-inductive DC circuit (1) comprises a DC+ rail (11), a DC− rail (12), and an insulation foil (15) disposed between the DC+ rail (11) and the DC− rail (12). The low-inductive DC circuit (1) is at least partially cast with a gel (4).

### BACKGROUND

The present invention relates to a low-inductive DC circuit, as well as a power module with a low-inductive intermediate circuit.

By switching off a transistor, the voltage in power modules may increase abruptly due to parasitic inductances. This voltage spike may endanger the circuit breakers, which is why their blocking voltage must be set accordingly high or their switching frequency must be reduced.

The demand in power electronics for high efficiencies while increasing the switching frequencies reaches the limits of the semiconductor components, especially at higher power levels. Central parameters thereby are the parasitic inductances, the reduction of which lowers the risk of overloading the circuit breakers and reduces switching losses.

### SUMMARY

In contrast, the low-inductive DC circuit according to the disclosure has the advantage that by casting the intermediate circuit with a gel, the creepage distances between a DC+ rail and a DC− rail are reduced. This allows close guidance of the DC+ rail and the DC− rail to each other, whereby they can be designed with a small space requirement in such a way that the current is particularly low-inductively passed through the power rails. Due to the low inductance, it is possible to increase the switching frequencies of adjacent circuit breakers or to design the circuit breakers for a lower blocking voltage. According to the disclosure, this is achieved in that a low-inductive DC circuit between a circuit breaker and a passive electrical component comprises a DC+ rail and a DC− rail, which are separated from one another by an insulation foil. The low-inductive DC circuit is additionally at least partially enclosed by a gel.

The gel is preferably cast in the liquid state in vacuo over the low-inductive DC circuit and then cross-linked, thereby hardening it. Preferably, the gel is a silicone gel which has good electrical insulation properties. The casting of the low-inductive DC circuit with gel allows the DC+ rail and the DC− rail to be guided with a short distance to each other.

A low-inductive DC link is understood to be a DC link, which preferably has an inductance of less than 3 nH. The low-inductive DC link is preferably designed to transmit currents between 600 A and 900 A and voltages between 800 V and 1000 V. Due to the low inductance of 3 nH or less, fast switching frequencies are enabled even at high electrical voltages and currents.

The dependent claims disclose preferred further developments of the invention.

Preferably, the passive electrical component is a capacitor. In particular, the capacitor is a film capacitor. The capacitor allows for the storage of electrical energy in the vicinity of the circuit breakers. Thus, negative effects on the inductance can be prevented by an external power conduction.

Further preferably, the DC+ rail and the DC− rail are arranged parallel to one another. Parasitic inductances occur where the current encloses a particular surface. It is possible to reduce the inductance of the DC circuit due to the parallel and in particular flat current conduction through the DC+ and DC− rail.

Particularly preferably, the DC+ rail and the DC− rail are arranged at least partially above one another along the low-inductive DC circuit. By guiding the DC+ and the DC− rail in parallel above each other, a further reduction in inductance is possible.

Preferably, the low-inductive DC circuit comprises a first gel frame which provides a limit for the gel. The gel frame is configured to be produced by overmolding a peripheral region of the low-inductive DC circuit. The gel frame is preferably produced by injection molding process. Thus, a leakage-proof and reliable production of a gel-filled area around the low-inductive DC circuit is possible, whereby leakage currents can be reliably prevented during operation.

Further preferably, the low-inductive DC circuit comprises a first connection area, which is configured to form a bonded connection between the low-inductive DC circuit and the passive component. The bonded connection can be made, for example, by soldering or welding and allows a reduction of the electrical resistance of the low-inductive DC circuit.

In a preferred further development of the invention, the first connection region comprises a plurality of alternating DC+ contact regions on the DC+ rail and DC− contact regions on the DC− rail. The contact region is an essential source of parasitic inductances. Due to the alternating arrangement of a plurality of DC+ and DC− contact regions, there is a parallel connection of the inductances in the contact region, whereby the resulting total inductance of the low-inductive DC circuit can be reduced. The narrow alternating arrangement of the contact regions in limited space is made possible by the high insulation properties of the DC circuit according to the invention with the aid of the gel.

Preferably, the low-inductive DC circuit has a second connection region which is configured to be connected to the circuit breaker by wire bonding. In particular, the second connection region is arranged to be connected to the circuit breaker by laser bonding, since lower inductances can be achieved by laser bonding. By casting the second connection region, a dense arrangement of the different electrical potentials of the second connection region to each other is possible.

Particularly preferably, the second connection region comprises a plurality of alternating DC+ contact regions on the DC+ rail and DC− contact regions on the DC− rail. Thus, the parasitic inductance of the second connection region is divided into several parallel inductances, thereby reducing the overall inductance of the low-inductive DC circuit. The low-inductive DC circuit cast according to the invention allows a secure, dense current conduction of different electrical potentials in the second connection region.

Preferably, the first connection region comprises a second gel frame which provides a limit for the gel. The first connection region is thereby covered with the gel. Furthermore, preferably the second connection region comprises the first gel frame, so that the second connection region is also cast with the gel. Particularly preferably, the second gel frame is arranged on the opposite side of the first gel frame. Thus, for the first connection region and/or second connection region, a leakage-proof and reliable casting in a first and second gel-filled region can be enabled, whereby leakage currents can be reliably prevented during operation.

Further preferably, the first gel frame and the second gel frame are one piece. Thus, they can be manufactured quickly and cost-effectively in a manufacturing step.

Preferably, the insulation foil separating the DC+ rail and the DC− rail has a width of between 200 μm and 300 μm. In particular, the insulation foil has a width of 250 μm. Thus, the DC− and DC+ rails can be closely merged. The insulation foil is designed to reliably prevent leakage currents or voltage flashovers between the DC− and the DC+ rail. For example, the insulation foil may also be a ceramic substrate.

The invention further describes a power module comprising a circuit breaker, a DC circuit according to the invention, and a passive electrical component. The passive component is in particular a capacitor.

Preferably, the circuit breaker and the low-inductive DC circuit are at least partially arranged within the first gel frame and are overcast by a gel. Thus, at the same time the creepage distances within the circuit breaker and the low-inductive DC circuit can be reduced, thereby allowing a compact design of the power module.

### BRIEF DESCRIPTION OF THE DRAWINGS

A preferred exemplary embodiment of the invention is described in detail hereinafter with reference to the accompanying drawing. The drawings show:

FIG. 1 an exemplary schematic view of a front side of a power module according to a preferred embodiment,

FIG. 2 an exemplary schematic view of a rear side of the power module of FIG. 1,

FIG. 3 a schematic detail view of a second connection region on the front side of the power module of FIG. 1,

FIG. 4 a schematic detail view of a first connection region on the rear side of the power module of FIG. 2, and

FIG. 5 a schematic cross-sectional view of the power module of FIG. 1.

### DETAILED DESCRIPTION

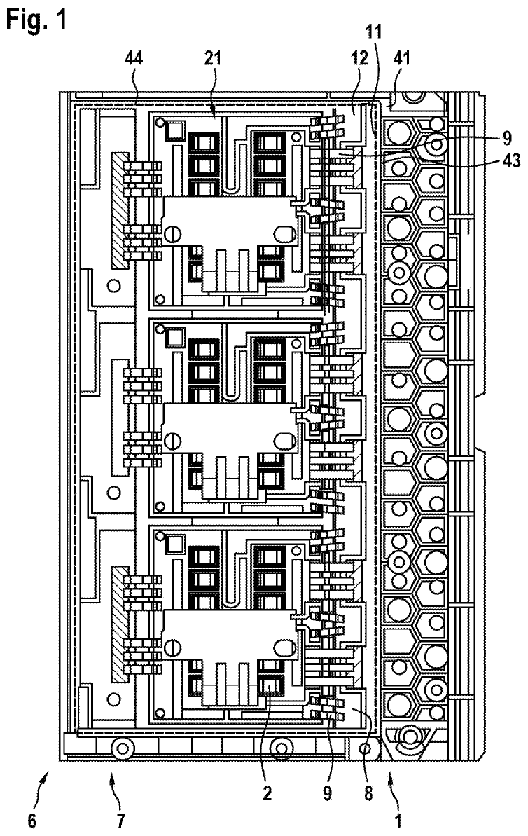

A power module with a low-inductive DC circuit 1 according to a preferred exemplary embodiment of the invention is described in detail in the following with reference to FIGS. 1 through 5.

FIG. 1 shows the power module 6 from a front side. The power module 6 comprises a plurality of circuit breakers 2, which are configured to convert a DC current from the low-inductive DC circuit 1 to a three-phase current on an AC side 7. To this end, the circuit breakers 2 are assigned three circuit breaker modules 21, which convert the DC current from the low-inductive DC circuit 1 to a phase of the three-phase current on the AC side 7, respectively.

The low-inductive DC circuit 1 comprises a DC+ rail 11 and a DC− rail 12. The DC+ rail 11 has two DC+ contact regions 51 per circuit breaker module 21, which are connected to the circuit breaker module 21 via three laser bond connections 9. An insulation foil is arranged between the DC+ rail 11 and the DC− rail 12, or between the DC+ contact region 51 and the DC− contact region 52, which electrically insulates the DC+ rail 11 and the DC− rail 12.

The DC− rail 12 has three DC contact regions 52 with two laser bond connections 9 per circuit breaker module 21. The DC− contact regions 52 are arranged alternately to the DC+ contact regions 51.

The low-inductive DC circuit 1, the circuit breaker 2, and the AC side 7 are arranged within a first gel frame 41 in a first gel-filled region 44. The first gel frame 41 represents a limit for a gel 4 with which the low-inductive DC circuit 1, the circuit breaker 2, and the AC side 7 are cast. Through the gel, it is possible to reduce creepage distances between different electrical potentials of the power module 6 and thus reduce the distances between components with different electrical potentials and reduce the inductance of the low-inductance DC circuit 1.

The first gel frame 41 is an injection-molded component having a wall region 43. The wall region 43 is arranged perpendicular to the surface of the power module 6 and limits the area in which the gel 4 can spread in the un-cross-linked state.

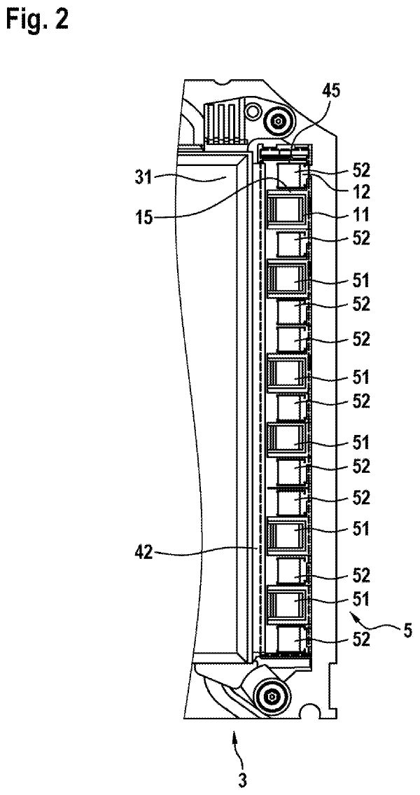

FIG. 2 schematically shows an excerpt of the rear side of the power module 6. On the rear side of the power module 6, a passive electrical component 3 is shown as a capacitor 31. The capacitor 31 is connected to the low-inductive DC circuit 1 via a first connection region 5 in a bonded manner.

The first connection region 5 comprises six DC+ contact regions 51 and nine DC− contact regions 52, which are arranged alternately with short distances to each other. The insulation foil 15 is arranged between the DC+ contact regions 51 and the DC− contact regions 52. The inductances of the DC+ contact regions 51 and the DC− contact regions 52 are connected in parallel, thereby reducing the overall inductance of the power module 6 and the low-inductance DC circuit 1. Alternatively, a higher or lower number of DC+ and DC− contact regions 51, 52 may also be provided in the first connection region 5.

A second gel frame 42 is arranged around the first contact region 5, which is filled with gel 4 and thus forms a second gel-filled region 45. The second gel frame 42 is connected to the first gel frame and is produced in the same injection molding process with the first gel frame 41. Thus, the first gel frame 41 and the second gel frame 42 are one piece.

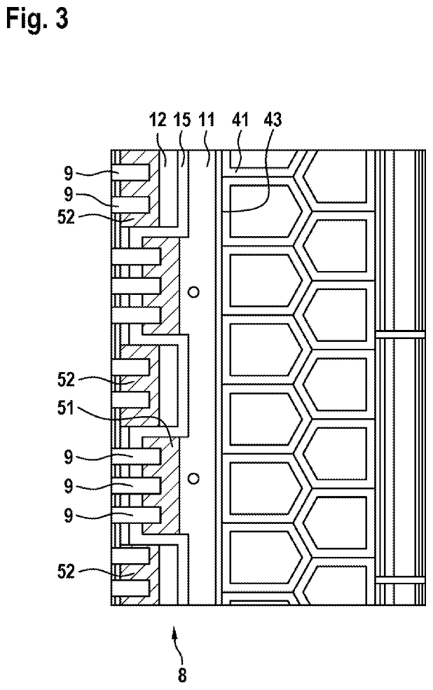

FIG. 3 shows a detail view of the front side of the power module 6 from FIG. 1 in the area of the second connection region 8. The DC+ rail 11 and the DC− rail 12 are arranged substantially parallel to one another in the second connection region 8, wherein the boundary between the DC+ rail 11 and the DC− rail 12 is configured in a meandering manner. Thus, in the second connection region 8, the DC+ rail 11 and the DC− rail 12 are interlocked with one another in a “castellated” manner. The intermediate region between the DC+ rail 11 and the DC− rail 12 is filled by the insulation foil 15.

The meandering shape of the intermediate region results in alternating DC+ contact regions 51 and DC− contact regions 52, which are configured to be connected to the circuit breaker modules 21 via laser bonding connections 9. In the design example, each DC+ contact region 51 comprises three laser bond connections 9. The DC− contact region 52 comprises either two laser bonding connections 9 connecting the DC− contact region 52 to a circuit breaker module 21, or four laser bonding connections 9, wherein two laser bonding connections 9 each connect the DC− contact region 52 to a circuit breaker module 21, and the two further laser bonding connections 9 connect the DC− contact region 52 to another circuit breaker module 21.

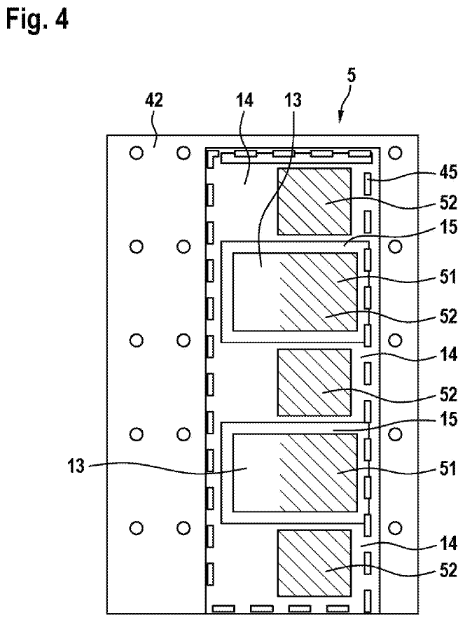

The second connection region 8 is adjoined by the first gel frame 41. In FIG. 4, a honeycomb structure of the first gel frame 41 is shown. The honeycomb structure allows for an increase in the mechanical properties of the low-inductive DC circuit 1 and reduces the material requirements of the first gel frame 41.

FIG. 4 shows a detail view of the rear of the power module 6 of FIG. 2. In FIG. 4, the capacitor 31 is hidden. The DC− rail 12 runs along the rear side of the power module 6, which has recesses in the first connection region 5, in which the DC+ contact region 51 is arranged. The DC+ contact region 51 is circumferentially separated from the DC− rail 12 by the insulation foil 15. Between the recesses, the DC− rail 12 has DC− contact regions 52. The DC contact regions 52 and DC+ contact regions 51 of the first connection region 5 are configured to form a bonded connection with the passive electrical component 3.

The first contact region 5 is delimited by the second gel frame 42. The second gel frame 42 has a rectangular recess for the DC− contact regions 52 and the DC+ contact regions 51.

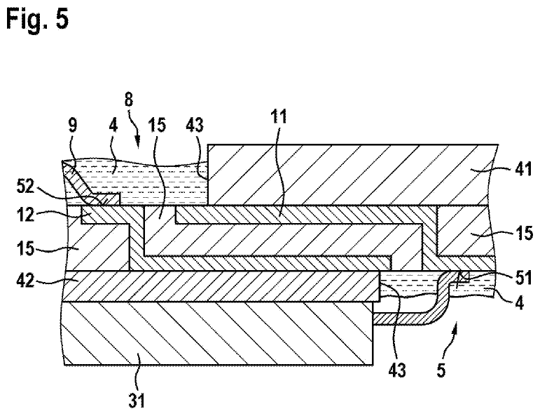

FIG. 5 shows a schematic cross-sectional diagram of the power module, according to the exemplary embodiment in FIG. 1, in the area of the low-inductive DC circuit 1.

The low-inductive DC circuit 1 comprises the DC+ rail 11 and the DC rail 12, which contact the circuit breakers 2 via a second connection region 8 and connect to the capacitor 31 in a first connection region 5. The circuit breakers 2, which are not shown in FIG. 5, are connected to the low-inductive DC circuit 1 via laser bonding connections 9.

In FIG. 5, the laser bond connection 9 is connected to the DC rail 12 via the DC contact region 52. The capacitor 31 is connected to the DC+ rail 11 via the DC+ contact region 51.

Laser bonding connections 9 to the DC+ contact region 51 and connections between the capacitor 31 and the DC− contact region 51 are not shown in FIG. 5.

The DC+ rail 11 and the DC− rail 12 run between the first connection region 5 and the second connection region 8 in parallel and arranged one above the other in a flat manner to each other. The inductance of the low-inductive DC circuit 1 can thus be kept to a minimum.

An insulation foil 15 is arranged between the DC+ rail 11 and the DC− rail 12.

On the layer of DC+ rail 11, DC− rail 12, and insulation foil 15, the first gel frame 41 is arranged on the front side and the second gel frame 42 on the rear side. The first gel frame 41 has a recess in the area of the second connection region 8, which is filled with gel 4. The second gel frame 42 has a recess in the area of the first connection region 5, which is also filled with gel 4. The recess is bounded in the first gel frame 41 and the second gel frame 42 by a wall region 43.

The capacitor 31 is arranged on the second gel frame 42.

1. A low-inductive DC circuit (1) configured to be positioned between a circuit breaker (2) and a passive electrical component (3), the low-inductive DC circuit (1) comprising:
a DC+ rail (11),
a DC− rail (12), and
an insulation foil (15) arranged between the DC+ rail (11) and the DC− rail (12),
wherein the low-inductive DC circuit (1) is at least partially cast from a gel (4).

2. The low-inductive DC circuit (1) according to claim 1, wherein the passive electrical component (3) comprises a film capacitor.

3. The low-inductive DC circuit (1) according to claim 2, wherein the DC+ rail (11) and the DC− rail (12) are arranged parallel to each other.

4. The low-inductive DC circuit (1) according to claim 3, wherein the DC+ rail (11) and the DC− rail (12) are arranged at least partially above each other along the low-inductive DC circuit (1).

5. The low-inductive DC circuit (1) according to claim 1, wherein the low-inductive DC circuit (1) comprises a first gel frame (41), which provides a limit for the gel (4), wherein the first gel frame (41) is formed by overmolding an edge region of the low-inductive DC circuit (1).

6. The low-inductive DC circuit (1) according to claim 1, wherein the low-inductive DC circuit (1) comprises a first connection region (5) which is configured to form a bonded connection between the low-inductive DC circuit (1) and the passive component (3).

7. The low-inductive DC circuit (1) according to claim 6, wherein the first connection region (5) comprises a plurality of alternating DC+ contact region (51) on the DC+ rail (11) and DC− contact regions (52) on the DC− rail (12).

8. The low-inductive DC circuit (1) according to claim 1, wherein the low-inductive DC circuit (1) comprises a second connection region (8), which is configured to be connected to the circuit breaker (2) by wire bonding.

9. The low-inductive DC circuit (1) according to claim 8, wherein the second connection region comprises a plurality of alternating DC+ contact regions (51) on the DC+ rail (11) and DC− contact regions (52) on the DC− rail (12).

10. The low-inductive DC circuits (1) according to claim 6, wherein the first connection region (5) comprises a second gel frame (42) providing a limit for the gel (4), wherein the first connection region (5) is cast with the gel (4) and/or wherein the second connection region (8) comprises the first gel frame (41), wherein the second connection region (8) is cast with the gel (4).

11. The low-inductive DC circuit (1) of claim 10, wherein the first gel frame (41) and the second gel frame (42) are one piece.

12. The low-inductive DC circuit (1) according to claim 1, wherein the insulation foil (15) separating the DC+ rail (11) and the DC− rail (12) has a width of between 200 μm and 300 μm.

13. A power module (6) comprising a circuit breaker (2), a DC circuit (1) according to claim 1, and a capacitor (31).

14. The power module (6) according to claim 13, wherein the circuit breaker (2) and the DC circuit (1) are at least partially arranged within a first gel frame (41) and are overcast by a gel (4).
